(19) United States
(12) Patent Application Publication
(10) Pub. No.: US 2024/0213747 A1
(43) Pub. Date: Jun. 27, 2024

(54) OPTICAL SEMICONDUCTOR ELEMENT

(71) Applicants: Sumitomo Electric Industries, Ltd., Osaka (JP); Sumitomo Electric Device Innovations, Inc., Yokohama-shi (JP)

(72) Inventors: Daisuke INOUE, Osaka-shi (JP); Konosuke AOYAMA, Yokohama-shi (JP)

(73) Assignees: Sumitomo Electric Industries, Ltd., Osaka (JP); Sumitomo Electric Device Innovations, Inc., Yokohama-shi (JP)

(21) Appl. No.: 18/390,432

(22) Filed: Dec. 20, 2023

(30) Foreign Application Priority Data
Dec. 26, 2022 (JP) 2022-208887

(51) Int. Cl. H01S 5/50; H01S 5/02; H01S 5/227

(52) U.S. Cl. CPC H01S 5/50; H01S 5/0206; H01S 5/2275

(57) ABSTRACT

An optical semiconductor element includes a substrate having a first main surface whose plane orientation is {100}, a first semiconductor layer provided on the first main surface and in which a mesa is formed, and a second semiconductor layer. The mesa has a laser portion and an optical amplifier portion. The laser portion has a first surface and a second surface. The optical amplifier portion has a third surface, a fourth surface, a fifth surface, a sixth surface, and an end surface. A first distance is smaller than a second distance. The first surface and the second surface are parallel to a {01-1} plane of the substrate. The end surface is perpendicular to the {01-1} plane. In a plane parallel to the first main surface, the third surface and the fourth surface are inclined from the {01-1} plane in directions identical to each other.

### CROSS REFERENCE TO RELATED APPLICATIONS

This application claims priority based on Japanese Patent Application No. 2022-208887 filed on Dec. 26, 2022, and the entire contents of the Japanese patent application are incorporated herein by reference.

### TECHNICAL FIELD

The present disclosure relates to an optical semiconductor element.

### BACKGROUND ART

An optical semiconductor element in which a distributed feedback (DFB) laser and a semiconductor optical amplifier are integrated is known.
PTL 1: U.S. Patent Application Publication No. 2012/0243074

### SUMMARY

An optical semiconductor element according to the present disclosure includes a substrate having a first main surface whose plane orientation is {100}, a first semiconductor layer provided on the first main surface and in which a mesa is formed, and a second semiconductor layer. The mesa has a laser portion and an optical amplifier portion. The laser portion has a first surface perpendicular to the first main surface, and a second surface perpendicular to the first main surface and parallel to the first surface. The optical amplifier portion has a third surface perpendicular to the first main surface and continuous with the first surface, a fourth surface perpendicular to the first main surface and continuous with the second surface, a fifth surface perpendicular to the first main surface and continuous with the third surface, a sixth surface perpendicular to the first main surface, continuous with the fourth surface, and parallel to the fifth surface, and an end surface perpendicular to the first main surface, continuous with the fifth surface and the sixth surface, and from which light is emitted. A first distance between the first surface and the second surface is smaller than a second distance between the fifth surface and the sixth surface. The first surface and the second surface are parallel to a {01-1} plane of the substrate. The end surface is perpendicular to the {01-1} plane. In a plane parallel to the first main surface, the third surface and the fourth surface are inclined from the {01-1} plane in directions identical to each other. In a plane parallel to the first main surface, the third surface is inclined more than the fourth surface from the {01-1} plane. In a plane parallel to the first main surface, the fifth surface and the sixth surface are inclined from the {01-1} plane in a direction identical to the directions in which the third surface and the fourth surface are inclined. The second semiconductor layer is in contact with the first surface, the second surface, the third surface, the fourth surface, the fifth surface, and the sixth surface.

### BRIEF DESCRIPTION OF THE DRAWINGS

FIG. 1 is a schematic diagram showing an optical semiconductor element according to a first embodiment.

FIG. 2 is a cross-sectional view (part 1) of an optical semiconductor element according to a first embodiment.

FIG. 3 is a cross-sectional view (part 2) of an optical semiconductor element according to a first embodiment.

FIG. 4 is a cross-sectional view (part 3) of an optical semiconductor element according to a first embodiment.

FIG. 5 is a cross-sectional view (part 4) of an optical semiconductor element according to a first embodiment.

FIG. 6 is a cross-sectional view (part 1) showing a method of manufacturing an optical semiconductor element according to a first embodiment.

FIG. 7 is a cross-sectional view (part 2) showing a method of manufacturing an optical semiconductor element according to a first embodiment.

FIG. 8 is a cross-sectional view (part 3) showing a method of manufacturing an optical semiconductor element according to a first embodiment.

FIG. 9 is a cross-sectional view (part 4) showing a method of manufacturing an optical semiconductor element according to a first embodiment.

FIG. 10 is a cross-sectional view (part 5) showing a method of manufacturing an optical semiconductor element according to a first embodiment.

FIG. 11 is a cross-sectional view (part 6) showing a method of manufacturing an optical semiconductor element according to a first embodiment.

FIG. 12 is a cross-sectional view (part 7) showing a method of manufacturing an optical semiconductor element according to a first embodiment.

FIG. 13 is a cross-sectional view (part 8) showing a method of manufacturing an optical semiconductor element according to a first embodiment.

FIG. 14 is a cross-sectional view (part 9) showing a method of manufacturing an optical semiconductor element according to a first embodiment.

FIG. 15 is a cross-sectional view (part 10) showing a method of manufacturing an optical semiconductor element according to a first embodiment.

FIG. 16 is a diagram showing a relationship between an incline angle and a reflectivity at an end surface.

FIG. 17 is a schematic diagram showing an optical semiconductor element according to a second embodiment.

FIG. 18 is a schematic diagram showing an optical semiconductor element according to a third embodiment.

FIG. 19 is a schematic diagram showing an optical semiconductor element according to a fourth embodiment.

FIG. 20 is a diagram showing a relationship between a current applied to an optical amplifier portion and a light output of an optical semiconductor element.

### DETAILED DESCRIPTION

Recently, it has been desired to improve the output of optical semiconductor elements.

It is an object of the present disclosure to provide an optical semiconductor element capable of enhancing output.

### Description of Embodiments of Present Disclosure

First, embodiments of the present disclosure will be listed and explained. In the following description, identical or corresponding elements are provided with the same reference numerals and will not be described repeatedly. Regarding crystallographic indication in the present disclosure, a crystal direction is represented by a square bracket [hkl] where h, k, 1 are Miller indices, a set of all directions that are equivalent to [hkl] is represented by <hkl>, a plane orientation is represented by (hkl), and a set of all plane orientations that are equivalent to (hkl) is represented by {hkl}. Generally, a negative crystallographic index is indicated by putting “−” (bar) above a numeral but is indicated by putting the negative sign before the numeral in the present disclosure. Also, when viewed from an arbitrary point, a side of the substrate may be referred to as an upward, an upper side, or a top, and a [−100] side of the substrate may be referred to as a downward, a lower side, or a bottom. In the present disclosure, the term “parallel” may include “substantially parallel”, and the term “perpendicular” may include “substantially perpendicular”. For example, “substantially parallel” means that even if two lines or two planes are not completely parallel to each other, they can be treated as parallel to each other within an allowable range in manufacturing. The term “substantially perpendicular” is also intended to apply to it as long as the mutual positional relationship between two lines or surfaces is within a range allowable in manufacturing, similarly to “substantially parallel”.

[1] An optical semiconductor element according to an embodiment of the present disclosure includes a substrate having a first main surface whose plane orientation is {100}, a first semiconductor layer provided on the first main surface and in which a mesa is formed, and a second semiconductor layer. The mesa has a laser portion and an optical amplifier portion. The laser portion has a first surface perpendicular to the first main surface, and a second surface perpendicular to the first main surface and parallel to the first surface. The optical amplifier portion has a third surface perpendicular to the first main surface and continuous with the first surface, a fourth surface perpendicular to the first main surface and continuous with the second surface, a fifth surface perpendicular to the first main surface and continuous with the third surface, a sixth surface perpendicular to the first main surface, continuous with the fourth surface, and parallel to the fifth surface, and an end surface perpendicular to the first main surface, continuous with the fifth surface and the sixth surface, and from which light is emitted. A first distance between the first surface and the second surface is smaller than a second distance between the fifth surface and the sixth surface. The first surface and the second surface are parallel to a {01-1} plane of the substrate. The end surface is perpendicular to the {01-1} plane. In a plane parallel to the first main surface, the third surface and the fourth surface are inclined from the {01-1} plane in directions identical to each other. In a plane parallel to the first main surface, the third surface is inclined more than the fourth surface from the {01-1} plane. In a plane parallel to the first main surface, the fifth surface and the sixth surface are inclined from the {01-1} plane in a direction identical to the directions in which the third surface and the fourth surface are inclined. The second semiconductor layer is in contact with the first surface, the second surface, the third surface, the fourth surface, the fifth surface, and the sixth surface.

In a plane parallel to the first main surface, the fifth surface and the sixth surface are inclined from the {01-1} plane in a direction identical to the directions in which the third surface and the fourth surface are inclined, and an optical axis of the optical amplifier portion is inclined from a direction perpendicular to the end surface. When the optical axis of the optical amplifier portion is inclined from the direction perpendicular to the end surface, the reflectivity at the end surface is lower than when the optical axis is not inclined from the direction perpendicular to the end surface. Therefore, reflection at the end surface is suppressed and a high output is obtained. Further, between the laser portion and the optical amplifier portion, the optical axes are not on a straight line and the traveling direction of the light in each portion is different. Since the second semiconductor layer is provided, the light is confined around the mesa and the radiation of the light to the outside from the mesa is suppressed. Therefore, the output can be improved.

[2] In [1], in a plane parallel to the first main surface, the fifth surface and the sixth surface may be inclined at 6° to 8° from the {01-1} plane in a direction identical to the directions in which the third surface and the fourth surface are inclined. In this case, the reflectivity is particularly low and an excellent output is obtained.

[3] In [1] or [2], in a plane parallel to the first main surface, the third surface may be inclined from the {01-1} plane more by an angle of 0° to 1° than the fifth surface. In this case, the inclination of the third surface from the {01-1} plane is small, and good light coupling efficiency can be obtained between the portion having the third surface and the portion having the fifth surface in the optical amplifier portion.

[4] In any one of [1] to [3], in a plane parallel to the first main surface, the fourth surface may be inclined from the {01-1} plane less by an angle larger than 0° and smaller than or equal to 3° than the sixth surface. In this case, in the optical amplifier portion, the deviation of the optical axes between the portion having the fourth surface and the portion having the sixth surface is suppressed to be small.

[5] In any one of [1] to [4], a size of an inclination of the fifth surface from the third surface may be equal to a size of an inclination of the sixth surface from the fourth surface. In this case, in the optical amplifier portion, the optical axes are coincident between the portion having the third surface and the fourth surface and the portion having the fifth surface and the sixth surface.

[6] In any one of [1] to [4], the third surface and the fifth surface may be flush with each other. In this case, the inclination of the third surface from the {01-1} plane can be reduced.

[7] In any one of [1] to [6], the substrate may be an indium phosphide substrate. In this case, a high output is easily obtained.

### Details of Embodiments of Present Disclosure

### First Embodiment

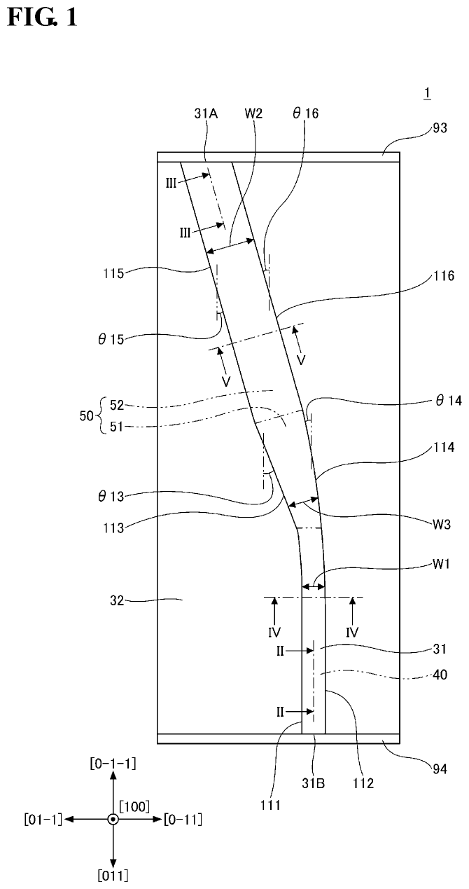

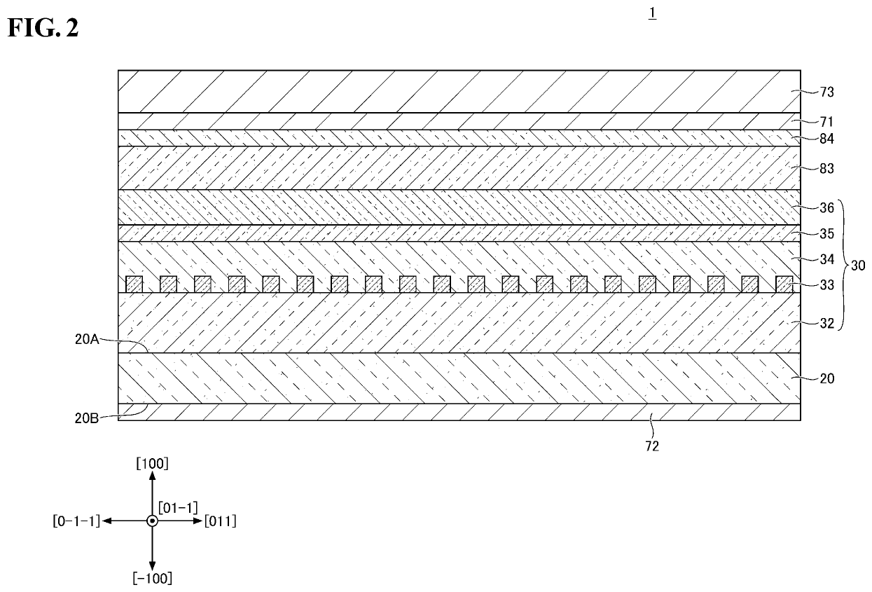

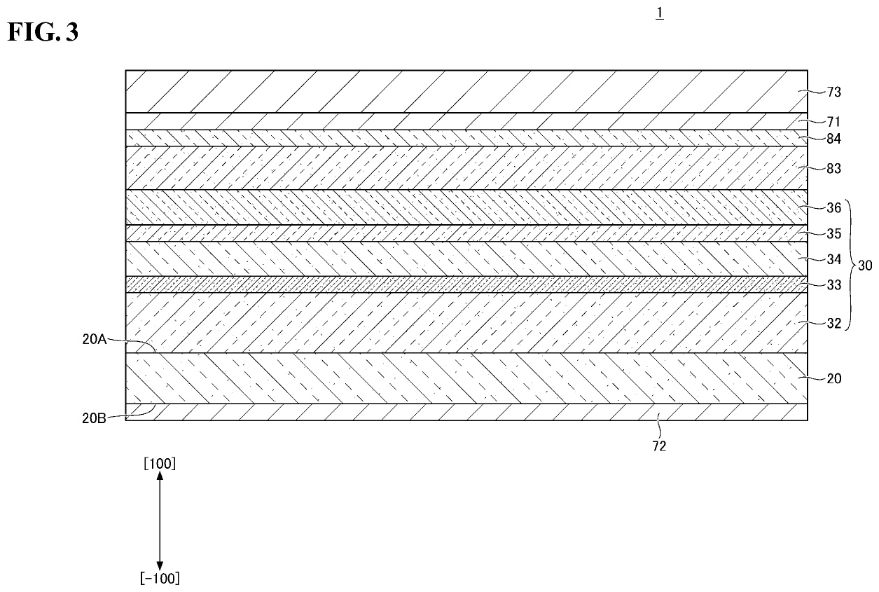

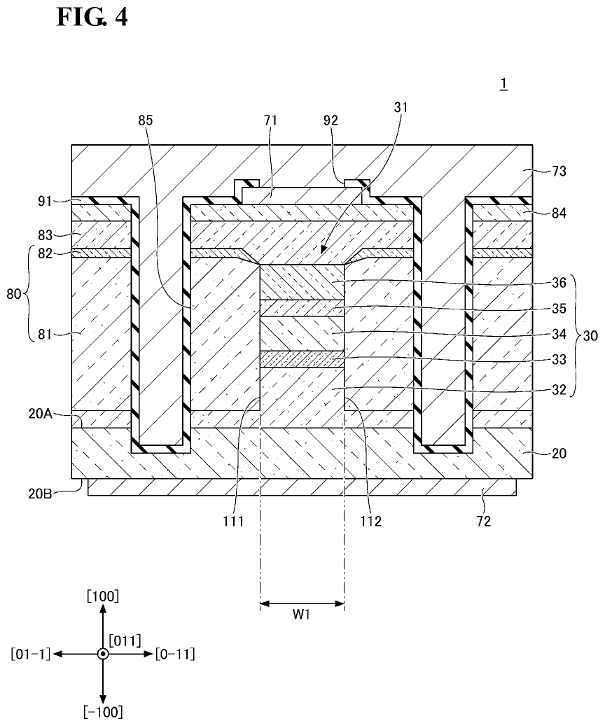

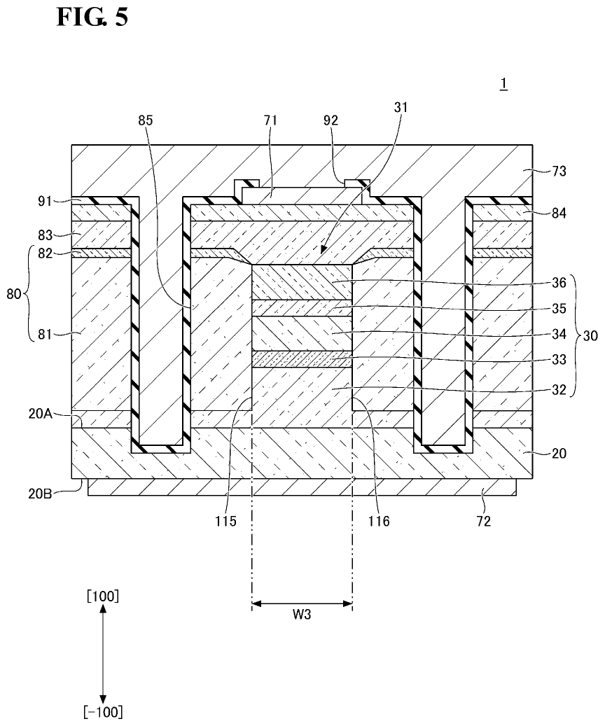

A first embodiment will be described. The first embodiment relates to an optical semiconductor element. FIG. 1 is a schematic diagram showing an optical semiconductor element according to the first embodiment. FIGS. 2 to 5 are cross-sectional views of the optical semiconductor element according to the first embodiment. FIG. 1 shows a shape of a mesa in plan view. FIG. 2 corresponds to a cross-sectional view along the line II-II in FIG. 1. FIG. 3 corresponds to a cross-sectional view along the line III-III in FIG. 1. FIG. 4 corresponds to a cross-sectional view along the line IV-IV in FIG. 1. FIG. 5 corresponds to a cross-sectional view along the line V-V in FIG. 1.

As shown in FIGS. 1 to 5, an optical semiconductor element 1 according to the first embodiment mainly includes a substrate 20, a semiconductor layer 30, and a semiconductor layer 80.

Substrate 20 is, for example, an n-type indium phosphide (InP) substrate. Substrate 20 has a first main surface 20A and a second main surface 20B opposite to first main surface 20A. Substrate 20 is doped with silicon (Si) or sulfur (S) at a concentration of, for example, 1.0×10¹⁸ cm⁻³. A plane orientation of first main surface 20A is (100), and a plane orientation of second main surface 20B is (−100).

Semiconductor layer 30 is provided on first main surface 20A. Semiconductor layer 30 includes a buffer layer 32, a diffraction grating layer 33, an n-type cladding layer 34, an active layer 35, and a p-type cladding layer 36. Semiconductor layer 30 is an example of a first semiconductor layer.

Buffer layer 32 is provided on substrate 20. Buffer layer 32 is, for example, an n-type InP layer having a thickness of about 500 nm. Buffer layer 32 is doped with Si at a concentration of 5.0×10¹⁷ cm⁻³, for example. Buffer layer 32 inherits the crystal orientation of substrate 20.

Diffraction grating layer 33 is provided on buffer layer 32. Diffraction grating layer 33 is, for example, an n-type gallium indium arsenide phosphide (GaInAsP) layer having a thickness of about 50 nm. The bandgap wavelength λg of diffraction grating layer 33 at room temperature is about 1.15 μm. Diffraction grating layer 33 is doped with Si at a concentration of, for example, 5.0×10¹⁷ cm⁻³. Diffraction grating layer 33 inherits the crystal orientation of buffer layer 32.

N-type cladding layer 34 is provided on diffraction grating layer 33 and buffer layer 32. N-type cladding layer 34 covers diffraction grating layer 33. N-type cladding layer 34 is, for example, an n-type InP layer having a thickness of about 500 nm. N-type cladding layer 34 is doped with Si at a concentration of, for example, 5.0×10¹⁷ cm⁻³. N-type cladding layer 34 inherits the crystal orientations of diffraction grating layer 33 and buffer layer 32.

Active layer 35 is provided on n-type cladding layer 34. Active layer 35 includes a quantum well layer and two barrier layers sandwiching the quantum well layer therebetween. The quantum well layer is, for example, a GaInAsP layer or an aluminum gallium indium arsenide (AlGaInAs) layer having a thickness of 80 nm. Each of the barrier layers is, for example, a GaInAsP layer or an AlGaInAs layer having a thickness of about 30 nm. The bandgap wavelength λg of the barrier layer at room temperature is about 1.15 μm. Active layer 35 inherits the crystal orientation of n-type cladding layer 34.

P-type cladding layer 36 is provided on active layer 35. P-type cladding layer 36 is, for example, a p-type InP layer having a thickness of about 200 nm. P-type cladding layer 36 is doped with zinc (Zn) at a concentration of, for example, 5.0×10¹⁷ cm⁻³. P-type cladding layer 36 inherits the crystal orientation of active layer 35.

Semiconductor layer 30 inherits the crystal orientation of substrate 20. The crystal orientation in the following description is the crystal orientation of substrate 20. A mesa 31 is formed in semiconductor layer 30. Mesa 31 is formed so that a part of buffer layer 32 is exposed from the mesa. Mesa 31 has a height of, for example, about 1000 nm. Mesa 31 includes a laser portion 40 and an optical amplifier portion 50. As shown in FIG. 1, laser portion 40 extends substantially parallel to a [0-1-1] direction, and optical amplifier portion 50 extends substantially parallel to a direction that is inclined from the [0-1-1] direction toward the [01-1] direction by 6° to 8°, which will be described in detail later. Optical amplifier portion 50 is connected to an end of the [0-1-1] side of laser portion 40. A dimension of laser portion 40 in the direction parallel to the [0-1-1] direction is, for example, 350 μm to 1000 μm. A dimension of optical amplifier portion 50 in the direction parallel to the [0-1-1] direction is, for example, 500 μm to 1800 μm.

Laser portion 40 has a first surface 111 and a second surface 112 that are perpendicular to first main surface 20A. A plane orientation of first surface 111 is (01-1), and a plane orientation of second surface 112 is (0-11). In other words, first surface 111 and second surface 112 are parallel to a {01-1} plane. A first distance W1 between first surface 111 and second surface 112 is, for example, 1.5 μm to 2.5 μm.

Optical amplifier portion 50 has a tapered portion 51 and a parallel portion 52. Tapered portion 51 is connected to an end portion of laser portion 40 on the [0-1-1] side of the laser portion 40. Parallel portion 52 is connected to an end portion of tapered portion 51.

Tapered portion 51 has a third surface 113 and a fourth surface 114 that are perpendicular to first main surface 20A. Third surface 113 is continuous with first surface 111, and fourth surface 114 is continuous with second surface 112. In a plane parallel to first main surface 20A, third surface 113 and fourth surface 114 are respectively inclined from a (01-1) plane and a (0-11) plane in directions identical to each other. The direction in which third surface 113 and fourth surface 114 are inclined is a direction parallel to a (100) plane. The inclination from the (01-1) plane of third surface 113 is more than the inclination from the (0-11) plane of fourth surface 114. That is, in a plane parallel to first main surface 20A, third surface 113 is inclined more than fourth surface 114 from the {01-1} plane. Therefore, a third distance W3 between third surface 113 and fourth surface 114 gradually increases as the distance from laser portion 40 increases. The magnitude of the angle formed by third surface 113 and the (01-1) plane is an angle θ13, the magnitude of the angle formed by fourth surface 114 and the (0-11) plane is an angle θ14, and angle θ13 is larger than angle θ14. In the present disclosure, the magnitude of the angle formed by two planes is 0° to 90°. In addition, the magnitude of the angle formed by two planes can be measured through, for example, microscopic observation.

Parallel portion 52 has a fifth surface 115 and a sixth surface 116 that are perpendicular to first main surface 20A. Fifth surface 115 and sixth surface 116 are parallel to each other. A second distance W2 between fifth surface 115 and sixth surface 116 is greater than first distance W1. In other words, first distance W1 is smaller than second distance W2. Second distance W2 is, for example, 2.0 μm to 10 μm. In a plane parallel to first main surface 20A, fifth surface 115 and sixth surface 116 are respectively inclined from the (01-1) plane and the (0-11) plane in a direction identical to the directions in which third surface 113 and fourth surface 114 are inclined. For example, in a plane parallel to first main surface 20A, fifth surface 115 and sixth surface 116 are respectively inclined at 6° to 8° from the (01-1) plane and the (0-11) plane in a direction identical to the directions in which third surface 113 and fourth surface 114 are inclined. The magnitude of the angle formed by fifth surface 115 and the (01-1) plane is an angle θ15, the magnitude of the angle formed by sixth surface 116 and the (0-11) plane is an angle θ16, and angle θ15 and angle θ16 are equal to each other and are, for example, 6° to 8°.

In the first embodiment, third surface 113 and fifth surface 115 are inclined such that the normal vectors point between the [01-1] direction and a direction, and fourth surface 114 and sixth surface 116 are inclined such that the normal vectors point between a [0-11] direction and the [0-1-1] direction.

In a plane parallel to first main surface 20A, fifth surface 115 is inclined less than third surface 113 from the (01-1) plane. In other words, in a plane parallel to first main surface 20A, third surface 113 is inclined more than fifth surface 115 from the (01-1) plane. For example, in a plane parallel to first main surface 20A, third surface 113 is inclined from the (01-1) plane more by an angle larger than 0° and smaller than or equal to 1° than fifth surface 115. Angle ƒ13 is larger than angle θ15, and for example, the difference between angle θ13 and angle θ15 is larger than 0° and smaller than or equal to 1°.

In a plane parallel to first main surface 20A, sixth surface 116 is inclined more than fourth surface 114 from the (0-11) plane. In other words, in a plane parallel to first main surface 20A, fourth surface 114 is inclined less than sixth surface 116 from the (0-11) plane. For example, in a plane parallel to first main surface 20A, fourth surface 114 is inclined from the (0-11) plane less by an angle lager than 0° and smaller than or equal to 1° than sixth surface 116. Angle θ16 is larger than angle θ14, and for example, the difference between angle θ16 and angle θ14 is larger than 0° and smaller than or equal to 1°.

For example, the difference between angle θ13 and angle θ15 is equal to the difference between angle θ16 and angle θ14, and at the boundary between tapered portion 51 and parallel portion 52, the optical axis of tapered portion 51 and the optical axis of parallel portion 52 are connected to each other and are parallel to each other. The optical axis of parallel portion 52 is, for example, inclined at 6° to 8° from the [0-1-1] direction.

As shown in FIG. 2, in laser portion 40, a diffraction grating having a constant period is formed in diffraction grating layer 33. On the other hand, as shown in FIG. 3, no diffraction grating is formed in diffraction grating layer 33 in optical amplifier portion 50, and the entire upper surface of buffer layer 32 is covered with diffraction grating layer 33 in mesa 31.

Semiconductor layer 80 is provided on both sides of mesa 31 so as to bury mesa 31. Semiconductor layer 80 has a p-type block layer 81 and an n-type block layer 82. Semiconductor layer 80 is in contact with first surface 111, second surface 112, third surface 113, fourth surface 114, fifth surface 115, and sixth surface 116. Semiconductor layer 80 is an example of a second semiconductor layer. At least a portion of the upper surface of p-type cladding layer 36 is exposed from semiconductor layer 80.

P-type block layer 81 is provided on buffer layer 32. P-type block layer 81 is in contact with first surface 111, second surface 112, third surface 113, fourth surface 114, fifth surface 115, and sixth surface 116. P-type block layer 81 is in contact with each side surface of buffer layer 32, diffraction grating layer 33, n-type cladding layer 34, active layer 35, and p-type cladding layer 36. P-type block layer 81 is, for example, a p-type InP layer whose thickness of the thickest portion is 1000 nm to 1500 nm. P-type block layer 81 is doped with Zn at a concentration of, for example, 1.0×10¹⁷ cm-3 to 1.0×10¹⁸ cm⁻³. Chlorine (Cl) may be added to a part of p-type block layer 81.

N-type block layer 82 is provided on p-type block layer 81. N-type block layer 82 is, for example, an n-type InP layer whose thickness of the thickest portion is 300 nm to 500 nm. N-type block layer 82 is doped with Si at a concentration of, for example, about 5.0×10¹⁸ cm⁻³. Cl may be added to a part of n-type block layer 82.

Optical semiconductor element 1 further includes a p-type semiconductor layer 83, a contact layer 84, an electrode 71, an electrode 72, a wiring 73, an insulating film 91, an antireflection film 93, and a high reflection film 94.

P-type semiconductor layer 83 is provided on p-type cladding layer 36 and n-type block layer 82. P-type semiconductor layer 83 is, for example, a p-type InP layer whose thickness of the thickest portion is 2500 nm to 3500 nm. P-type semiconductor layer 83 is doped with Zn at a concentration of, for example, 1.0×10¹⁸ cm⁻³ to 2.0×10¹⁸ cm⁻³. P-type semiconductor layer 83 can function as a part of p-type cladding layer 36.

Contact layer 84 is provided on p-type semiconductor layer 83. Contact layer 84 has a p-type GaInAsP layer and a p-type indium gallium arsenide (InGaAs) layer. The GaInAsP layer is provided on p-type semiconductor layer 83. For example, the GaInAsP layer has a thickness of about 200 nm and is doped with Zn at a concentration of about 2.0×10¹⁸ cm⁻³. The InGaAs layer is provided on the GaInAsP layer. For example, the InGaAs layer has a thickness of about 300 nm and is doped with Zn at a concentration of about 8.0×10¹⁸ cm⁻³. The band gap of contact layer 84 is smaller than that of p-type semiconductor layer 83.

Electrode 71 is provided on contact layer 84. Electrode 71 is provided so as to overlap mesa 31 in a plan view. For example, the contour of mesa 31 is inside the contour of electrode 71 in a plan view.

A trench 85 is formed in a stacked body of substrate 20, buffer layer 32, semiconductor layer 80, p-type semiconductor layer 83, and contact layer 84. Trench 85 is formed on the [01-1] side and the [0-11] side of mesa 31 so as to put mesa 31 in between. Trench 85 extends along mesa 31, for example.

Insulating film 91 covers the upper surface of contact layer 84, the upper surface and the side surface of electrode 71, and the inner wall surface and the bottom surface of trench 85. Insulating film 91 is, for example, a silicon oxide (SiO₂) film, a silicon oxynitride (SiON) film, or a silicon nitride (SiN) film. An opening portion 92 is formed in insulating film 91 to expose a portion of the upper surface of electrode 71.

Wiring 73 is provided on insulating film 91. Wiring 73 is also provided inside trench 85. Wiring 73 is in contact with electrode 71. Wiring 73 is, for example, Au wiring.

Electrode 72 is provided on second main surface 20B of substrate 20. Electrode 72 is in contact with substrate 20.

Contact layer 84, electrode 71 and wiring 73 are insulated and separated between laser portion 40 and optical amplifier portion 50, so that voltages can be applied to laser portion 40 and optical amplifier portion 50 independently with each other.

Mesa 31 has a first end surface 31A having a plane orientation of (0-1-1) and a second end surface 31B having a plane orientation of (011). Antireflection film 93 covers first end surface 31A, and high reflection film 94 covers second end surface 31B. For example, antireflection film 93 includes titanium oxide (TiO₂) or tantalum oxide (Ta₂O₃) as a high-refractive-index film and silicon oxide (SiO₂) or aluminum oxide (Al₂O₃) as a low-refractive-index film, and the low-refractive-index film is located between first end surface 31A and the high-refractive-index film. For example, high reflection film 94 includes titanium oxide (TiO₂) or tantalum oxide (Ta₂O₃) layer as a high-refractive-index film and silicon-oxide (SiO₂) or aluminum oxide (Al₂O₃) as a low-refractive-index film, and has a multilayer structure in which the low-refractive-index film is located between second end surface 31B and the high-refractive-index film is repeated two to five periods.

In optical semiconductor element 1, a portion including laser portion 40 of mesa 31 in plan view functions as a DFB laser, and a portion including optical amplifier portion 50 of mesa 31 in plan view functions as an SOA (semiconductor optical amplifier).

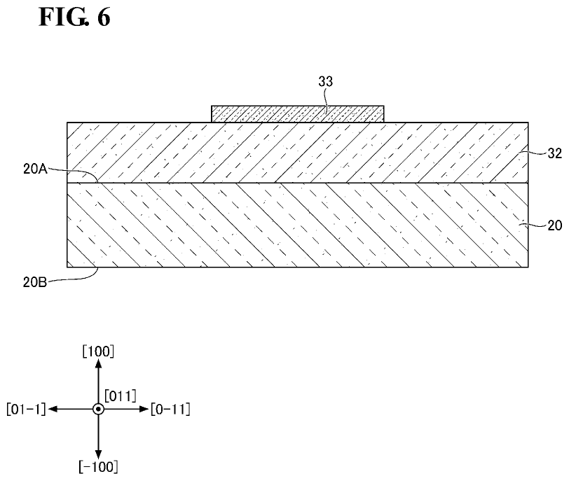

Next, a method of manufacturing optical semiconductor element 1 according to the first embodiment will be described. FIGS. 6 to 15 are cross-sectional views showing a method of manufacturing optical semiconductor element 1 according to the first embodiment. FIGS. 6 to 15 show the change of the cross section along the line IV-IV in FIG. 1.

First, as shown in FIG. 6, substrate 20 having first main surface 20A and second main surface 20B is prepared, and buffer layer 32 is formed on first main surface 20A. Next, diffraction grating layer 33 is formed on buffer layer 32. Diffraction grating layer 33 may be formed wider than the final dimension. In the portion included in laser portion 40, a diffraction grating is formed in diffraction grating layer 33 (see FIG. 2), and in the portion included in optical amplifier portion 50, the entire upper surface of buffer layer 32 is covered with diffraction grating layer 33.

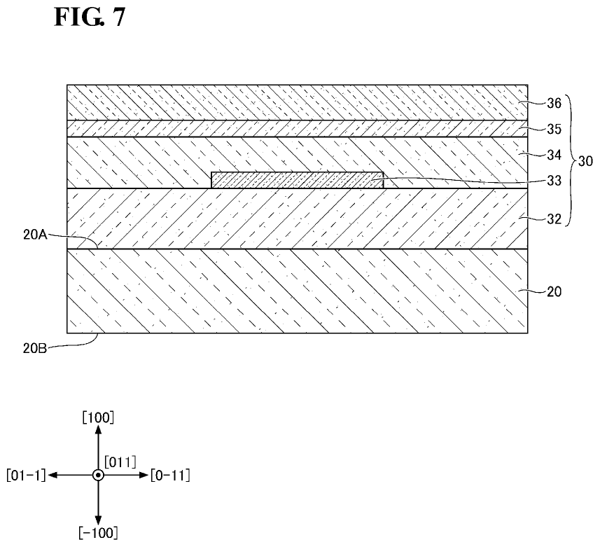

Next, as shown in FIG. 7, n-type cladding layer 34 is formed on diffraction grating layer 33 and buffer layer 32. N-type cladding layer 34 covers diffraction grating layer 33. Next, active layer 35 is formed on n-type cladding layer 34, and p-type cladding layer 36 is formed on active layer 35.

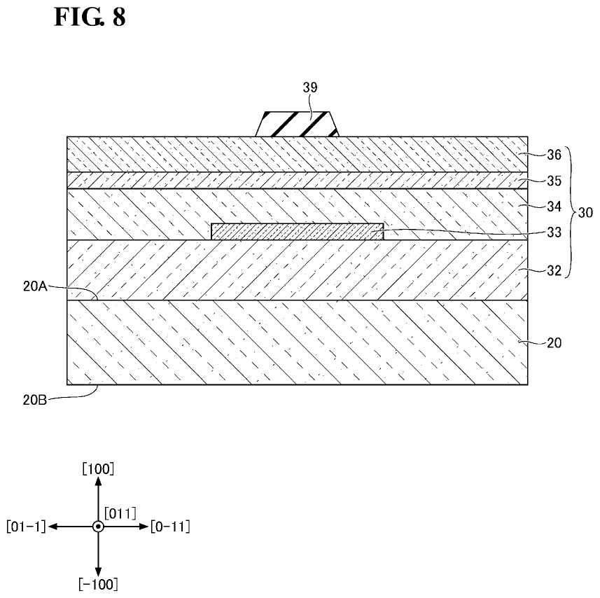

Next, as shown in FIG. 8, a mask 39 is formed on p-type cladding layer 36. Mask 39 is formed on the region where mesa 31 is to be formed. Mask 39 is, for example, a SiO₂ film.

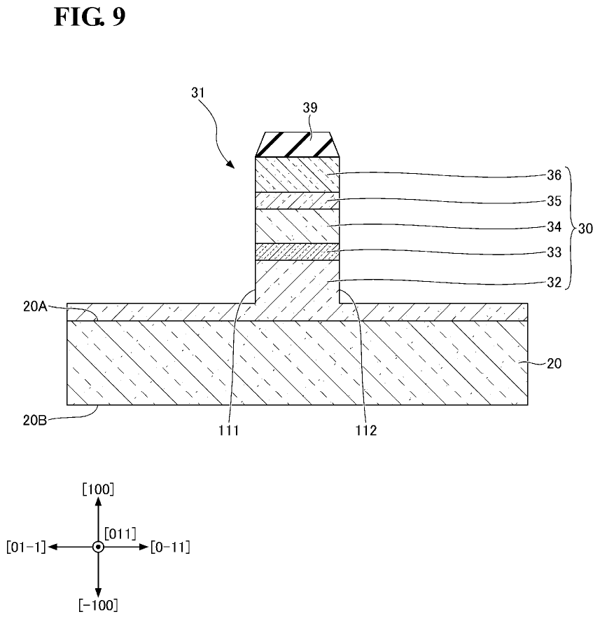

Next, as shown in FIG. 9, p-type cladding layer 36, active layer 35, n-type cladding layer 34, diffraction grating layer 33 and a part of buffer layer 32 are dry-etched using mask 39 as an etching mask. As a result, mesa 31 is formed. Mesa 31 has laser portion 40 and optical amplifier portion 50, and optical amplifier portion 50 includes tapered portion 51 and parallel portion 52. In addition, laser portion 40 has first surface 111 and second surface 112, tapered portion 51 has third surface 113 and fourth surface 114, and parallel portion 52 has fifth surface 115 and sixth surface 116. As the dry etching, for example, reactive ion etching (RIE) using silicon tetrachloride (SiCl₄) is performed.

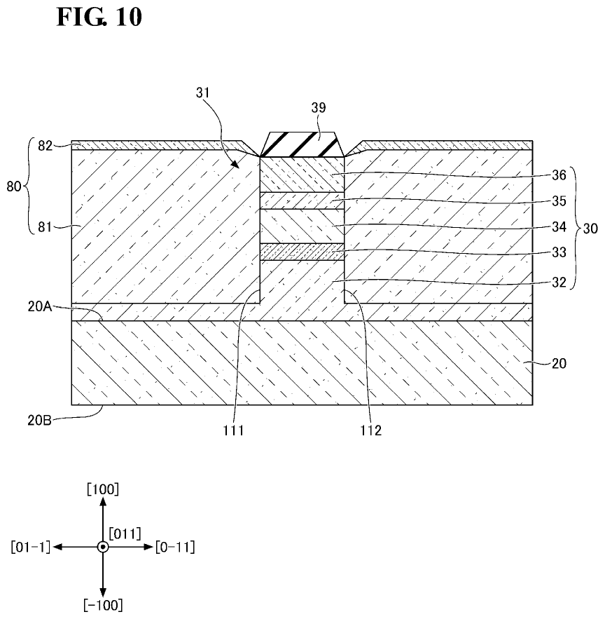

Next, as shown in FIG. 10, using mask 39 as a growth mask, p-type block layer 81 is formed on buffer layer 32 exposed from mesa 31, and n-type block layer 82 is formed on p-type block layer 81. As a result, mesa 31 is buried by semiconductor layer 80 including p-type block layer 81 and n-type block layer 82. Semiconductor layer 80 is in contact with first surface 111, second surface 112, third surface 113, fourth surface 114, fifth surface 115, and sixth surface 116.

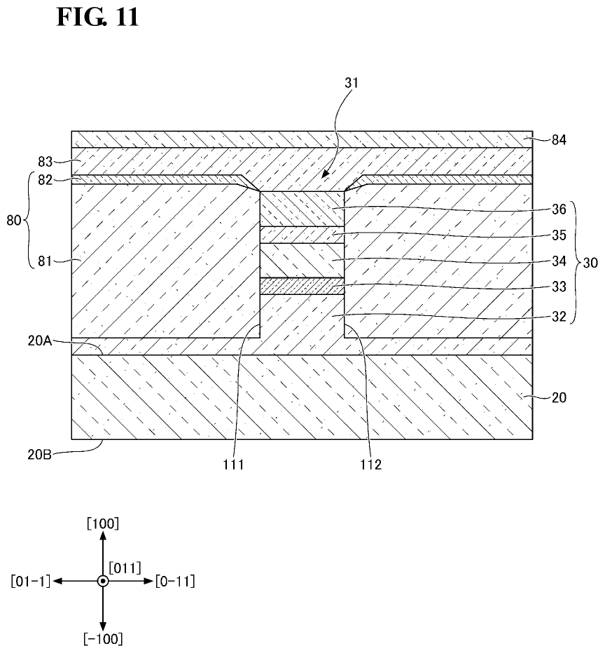

Next, as shown in FIG. 11, mask 39 is removed. Mask 39 can be removed using, for example, hydrofluoric acid (HF). Next, p-type semiconductor layer 83 is formed on p-type cladding layer 36 and n-type block layer 82, and contact layer 84 is formed on p-type semiconductor layer 83. P-type semiconductor layer 83 is integrated with p-type cladding layer 36.

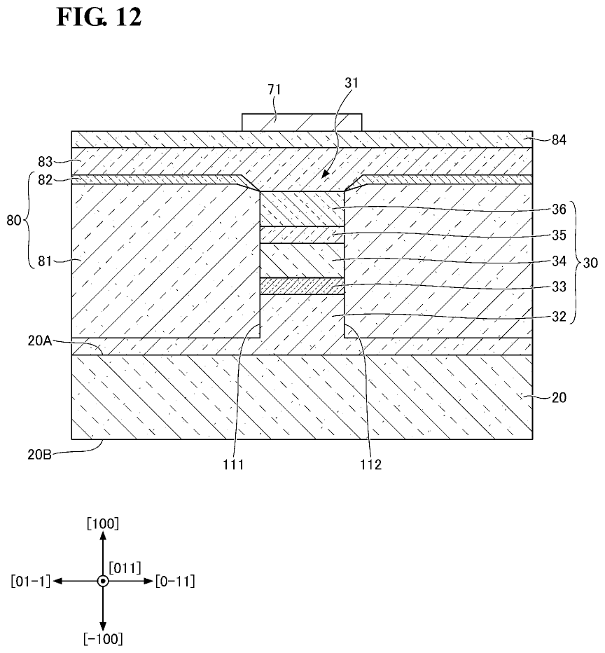

Next, as shown in FIG. 12, electrode 71 is formed on contact layer 84.

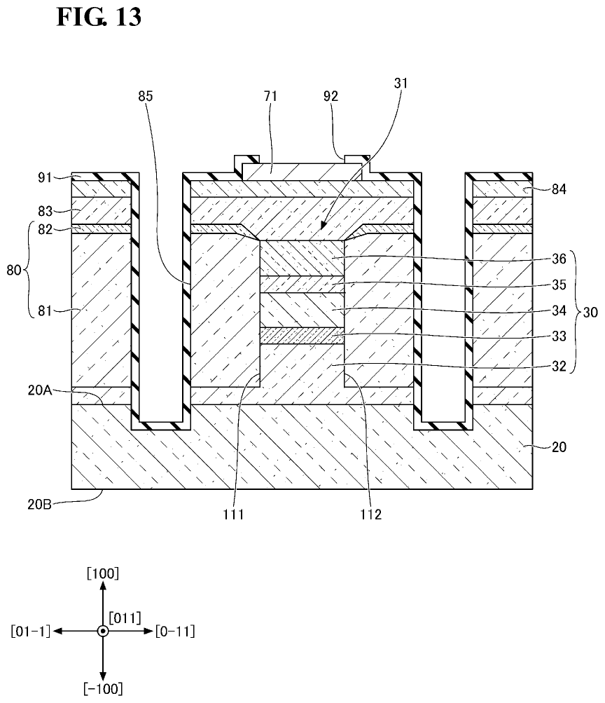

Next, as shown in FIG. 13, trench 85 is formed in the stacked body of substrate 20, buffer layer 32, semiconductor layer 80, p-type semiconductor layer 83, and contact layer 84. Trench 85 can be formed by, for example, dry etching using an etching mask (not shown). As the dry etching, for example, RIE using SiCl₄ is performed. Next, insulating film 91 is formed to cover the upper surface of contact layer 84, the upper surface and the side surface of electrode 71, and the inner wall surface and the bottom surface of trench 85, and opening portion 92 is formed in insulating film 91 to expose a portion of the top surface of electrode 71.

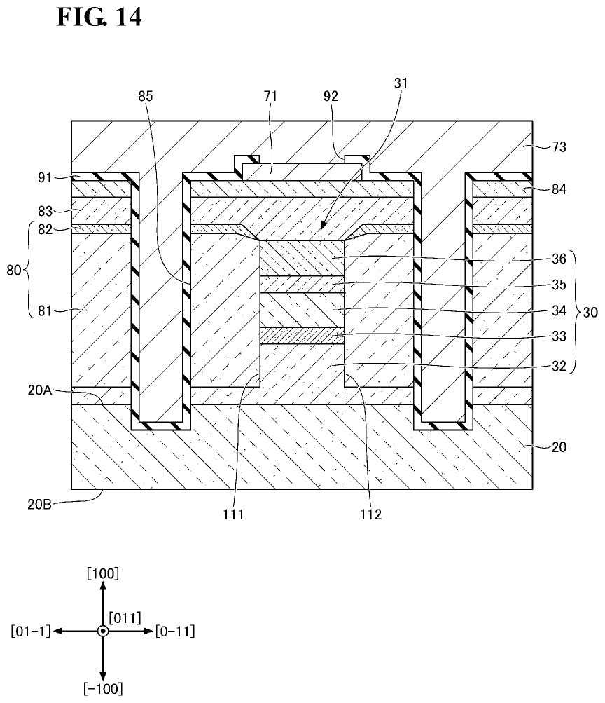

Next, as shown in FIG. 14, wiring 73 is formed on insulating film 91. Wiring 73 is also formed inside trench 85. Wiring 73 is in contact with electrode 71.

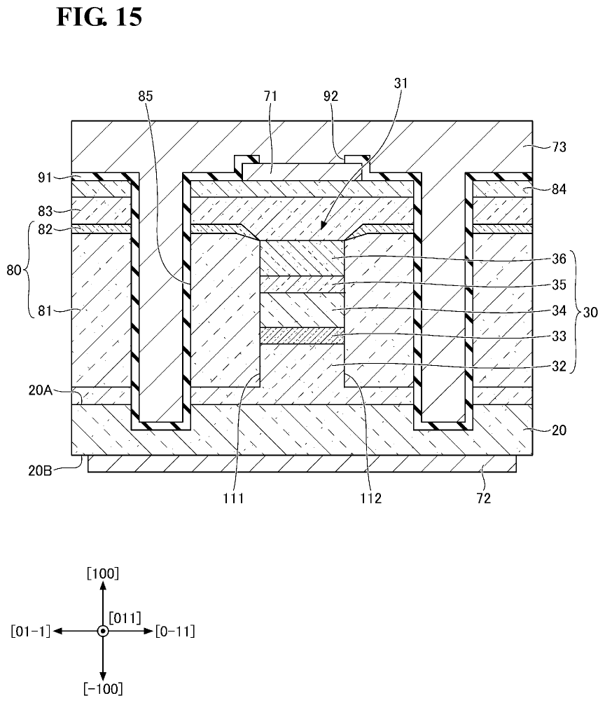

Next, as shown in FIG. 15, substrate 20 is polished from second main surface 20B. Next, electrode 72 in contact with substrate 20 is formed under second main surface 20B.

Next, antireflection film 93 covering first end surface 31A of mesa 31 and high reflection film 94 covering second end surface 31B are formed.

In this way, optical semiconductor element 1 according to the first embodiment can be manufactured.

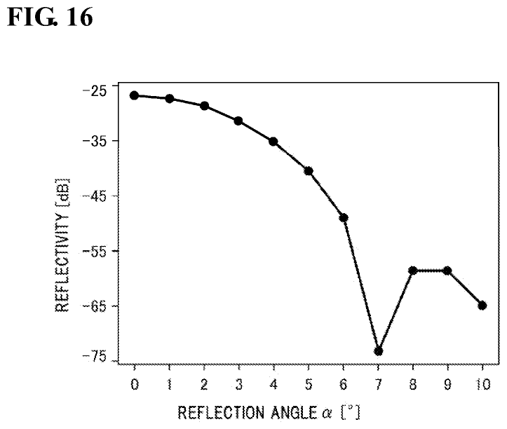

In optical semiconductor element 1, when a voltage is applied between electrode 71 and electrode 72, light is generated in laser portion 40, the light is amplified by optical amplifier portion 50, and laser light is emitted from first end surface 31A. In a plane parallel to first main surface 20A, fifth surface 115 and sixth surface 116 are respectively inclined from the (01-1) plane and the (0-11) plane in directions identical to the direction in which third surface 113 and fourth surface 114 are inclined, and the optical axis of optical amplifier portion 50 is inclined from the direction perpendicular to first end surface 31A. As shown in FIG. 16, when the optical axis of optical amplifier portion 50 is inclined from the direction perpendicular to first end surface 31A, i.e., when the alignment angle α is larger than 0°, the reflectivity at first end surface 31A is lower than when it is not inclined, i.e., when the alignment angle α is 0°. Therefore, in optical semiconductor element 1, reflection on first end surface 31A is suppressed, and a high output is obtained. When the incline angle α is 6° to 8°, the reflectivity is particularly low, and an excellent output is obtained. FIG. 16 is a diagram showing the relationship between the incline angle α and the reflectivity at first end surface 31A. The reflectivity is expressed in logarithm.

Between laser portion 40 and optical amplifier portion 50, the optical axis is not on a straight line and the traveling direction of the light is changed, but since semiconductor layer 80 is provided, the light is confined in mesa 31 and the leaking of the light from mesa 31 is suppressed.

When a surface having an excessively large inclination from the {01-1} plane is formed by etching, the difference in etching rate between the surface and a surface having a small inclination may become large. In addition, when a semiconductor layer is grown so as to be in contact with the plane having the excessively large inclination from the {01-1} plane in order to bury a mesa, there is a possibility that a difference in the progress of crystal growth between the surface having the excessively large inclination and the surface having the small inclination becomes large. The difference in the etching rate and the difference in the progress of the crystal growth may affect the stability of the manufacture of the optical semiconductor element and the reliability of the manufactured optical semiconductor element. In optical semiconductor element 1, among first surface 111, second surface 112, third surface 113, fourth surface 114, fifth surface 115, and sixth surface 116, third surface 113 is a surface having the highest order and the largest inclination from the {01-1} plane, and the difference between angle θ13 and angle θ15 is larger than 0° and smaller than or equal to 1°. Therefore, the inclination from the {01-1} plane is small, and the difference in the etching rate and the difference in the progress of the crystal growth are suppressed to be small.

When the difference between angle θ13 and angle θ15 is larger than 0° and smaller than or equal to 1° and the difference between angle θ16 and angle θ14 is larger than 0° and smaller than or equal to 1°, the inclinations of third surface 113 and fourth surface 114 from the {01-1} plane are small, and good light coupling efficiency can be obtained between tapered portion 51 and parallel portion 52.

When the size of the inclination of fifth surface 115 from third surface 113 is equal to the size of the inclination of sixth surface 116 from fourth surface 114, the optical axis of tapered portion 51 coincides with the optical axis of parallel portion 52.

When substrate 20 is an InP substrate, a high output is obtained.

### Second Embodiment

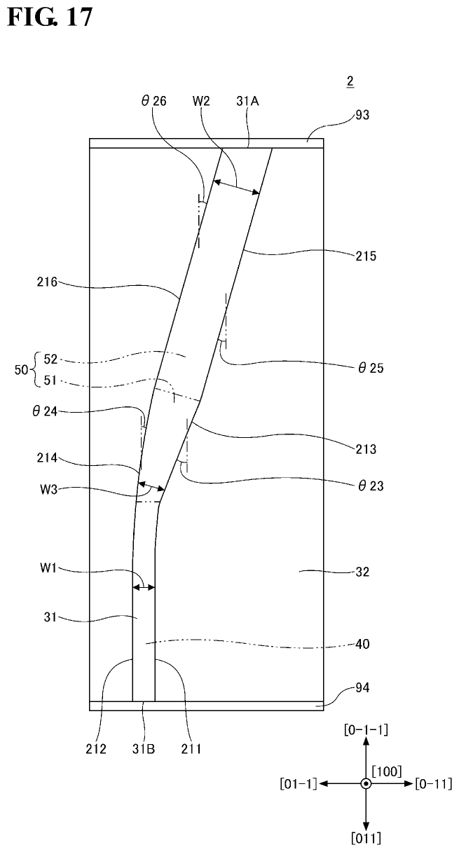

A second embodiment will be described. The second embodiment differs from the first embodiment primarily in the configuration of a mesa. FIG. 17 is a schematic diagram showing an optical semiconductor element according to the second embodiment. FIG. 17 shows the shape of the mesa in plan view.

As shown in FIG. 17, in an optical semiconductor element 2 according to the second embodiment, laser portion 40 has a first surface 211 and a second surface 212 perpendicular to first main surface 20A. The plane orientation of first surface 211 is (0-11), and the plane orientation of second surface 212 is (01-1). In other words, first surface 211 and second surface 212 are parallel to a {01-1} plane. First distance W1 between first surface 211 and second surface 212 is, for example, 1.5 μm to 2.5 μm.

Tapered portion 51 has a third surface 213 and a fourth surface 214 that are perpendicular to first main surface 20A. Third surface 213 is continuous with first surface 211, and fourth surface 214 is continuous with second surface 212. In a plane parallel to first main surface 20A, third surface 213 and fourth surface 214 are respectively inclined from a (0-11) plane and a (01-1) plane in directions identical to each other. The directions in which third surface 213 and fourth surface 214 are inclined are directions parallel to a (100) plane. The inclination from the (0-11) plane of third surface 213 is larger than the inclination from the (01-1) plane of fourth surface 214. That is, in a plane parallel to first main surface 20A, third surface 213 is inclined more than fourth surface 214 from the {01-1} plane. Therefore, third distance W3 between third surface 213 and fourth surface 214 gradually increases as the distance from laser portion 40 increases. The magnitude of the angle formed by third surface 213 and the (0-11) plane is an angle θ23, the magnitude of the angle formed by fourth surface 214 and the (01-1) plane is an angle θ24, and angle θ23 is larger than angle θ24.

Parallel portion 52 has a fifth surface 215 and a sixth surface 216 that are perpendicular to first main surface 20A. Fifth surface 215 and sixth surface 216 are parallel to each other. Second distance W2 between fifth surface 215 and sixth surface 216 is greater than first distance W1. In other words, first distance W1 is smaller than second distance W2. Second distance W2 is, for example, 2.0 μm to 10 μm. In a plane parallel to first main surface 20A, fifth surface 215 and sixth surface 216 are respectively inclined from the (0-11) plane and the (01-1) plane in a direction identical to the directions in which third surface 213 and fourth surface 214 are inclined. For example, in a plane parallel to first main surface 20A, fifth surface 215 and sixth surface 216 are respectively inclined at 6° to 8° from the (0-11) plane and from the (01-1) plane in a direction identical to the directions in which third surface 213 and fourth surface 214 are inclined. The magnitude of the angle formed by fifth surface 215 and the (0-11) plane is an angle θ25, the magnitude of the angle formed by sixth surface 216 and the (01-1) plane is an angle θ26, and angle θ25 and angle θ26 are equal to each other and are, for example, 6° to 8°.

In the second embodiment, third surface 213 and fifth surface 215 are inclined such that the normal vectors point between the [0-11] direction and the direction, and fourth surface 214 and sixth surface 216 are inclined such that the normal vectors point between the [01-1] direction and a [0-1-1] direction.

In a plane parallel to first main surface 20A, fifth surface 215 is inclined less than third surface 213 from the (0-11) plane. In other words, in a plane parallel to first main surface 20A, third surface 213 is inclined more than fifth surface 215 from the (0-11) plane. For example, in a plane parallel to first main surface 20A, third surface 213 is inclined from the (0-11) plane more by an angle larger than 0° and smaller than or equal to 1° than fifth surface 215. Angle θ23 is larger than angle θ25, and for example, the difference between angle θ23 and angle θ25 is larger than 0° and smaller than or equal to 1°.

In a plane parallel to first main surface 20A, sixth surface 216 is inclined more than fourth surface 214 from the (01-1) plane. In other words, in a plane parallel to first main surface 20A, fourth surface 214 is inclined less than sixth surface 216 from the (01-1) plane. For example, in a plane parallel to first main surface 20A, fourth surface 214 is inclined from the (01-1) plane less by an angle larger than 0° and smaller than or equal to 1° than sixth surface 216. Angle θ26 is larger than angle θ24, and for example, the difference between angle θ26 and angle θ24 is larger than 0° and smaller than or equal to 1°.

For example, the difference between angle θ23 and angle θ25 is equal to the difference between angle θ26 and angle θ24, and at the boundary between tapered portion 51 and parallel portion 52, the optical axis of tapered portion 51 and the optical axis of parallel portion 52 are connected to each other and are parallel to each other. The optical axis of parallel portion 52 is, for example, inclined at 6° to 8° from the [0-1-1] direction.

The other configurations of the second embodiment are similar to those of the first embodiment.

The same effect can be obtained with the second embodiment as with the first embodiment.

### Third Embodiment

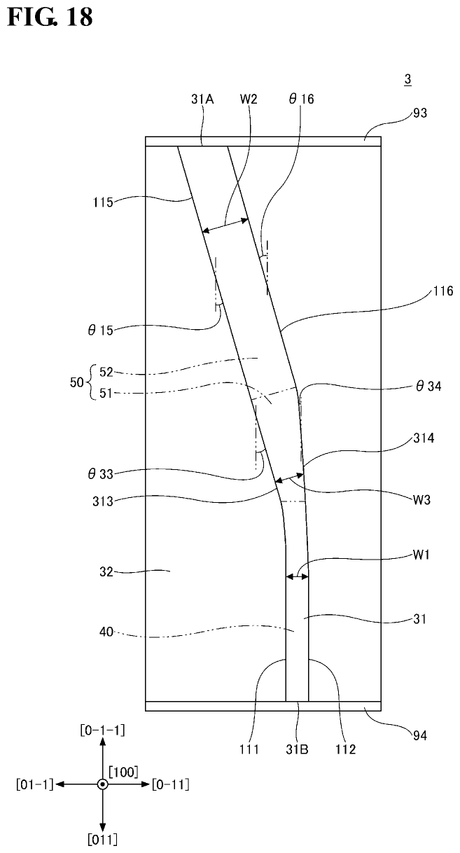

A third embodiment will be described. The third embodiment differs from the first embodiment primarily in the configuration of a tapered portion. FIG. 18 is a schematic diagram showing an optical semiconductor element according to the third embodiment. FIG. 18 shows the shape of a mesa in plan view.

As shown in FIG. 18, in an optical semiconductor element 3 according to the third embodiment, tapered portion 51 has a third surface 313 and a fourth surface 314 perpendicular to first main surface 20A. Third surface 313 is continuous with first surface 111 and fifth surface 115, and fourth surface 314 is continuous with second surface 112 and sixth surface 116. In a plane parallel to first main surface 20A, third surface 313 and fourth surface 314 are respectively inclined from a (01-1) plane and a (0-11) plane in directions identical to each other. The directions in which third surface 313 and fourth surface 314 are inclined are a directions parallel to a (100) plane. The inclination of third surface 313 from the (01-1) plane is larger than the inclination of fourth surface 314 from the (0-11) plane. That is, in a plane parallel to first main surface 20A, third surface 313 is inclined more than fourth surface 314 from a {01-1} plane. Therefore, third distance W3 between third surface 313 and fourth surface 314 gradually increases as the distance from laser portion 40 increases. The magnitude of the angle formed by third surface 313 and the (01-1) plane is an angle θ33, the magnitude of the angle formed by fourth surface 314 and the (0-11) plane is an angle θ34, and angle θ33 is larger than angle θ34.

Third surface 313 and fifth surface 115 are flush with each other. That is, in a plane parallel to first main surface 20A, the size of the inclination of third surface 313 from the (01-1) plane is equal to the size of the inclination of fifth surface 115 from the (01-1) plane. Thus, in a plane parallel to first main surface 20A, third surface 313 is inclined from the (01-1) plane more than fifth surface 115 by an angle larger than 0°. Angle θ33 is equal to angle θ15, and the difference between angle θ33 and angle θ15 is 0°.

In a plane parallel to first main surface 20A, fourth surface 314 is inclined from the (0-11) plane less by an angle larger than 0° and smaller than or equal to 3° than sixth surface 116, for example. For example, the difference between angle θ34 and angle θ16 is larger than 0° and smaller than or equal to 3°.

The other configurations of the third embodiment are similar to those of the first embodiment.

According to the third embodiment as well, reflection on first end surface 31A is suppressed and a high output is obtained. In addition, since semiconductor layer 80 is provided, light is confined in mesa 31, and emission of light to the outside of mesa 31 is suppressed.

Since third surface 313 and fifth surface 115 are flush with each other, the inclination of third surface 313 from the {01-1} plane is further suppressed, and the difference in the etching rate and the difference in the progress of the crystal growth are further suppressed.

In a plane parallel to first main surface 20A, fourth surface 314 is inclined from the (0-11) plane less by an angle larger than 0° and smaller than or equal to 3° than sixth surface 116, and it is easy to suppress the deviation of the optical axis between tapered portion 51 and parallel portion 52 to be small.

### Fourth Embodiment

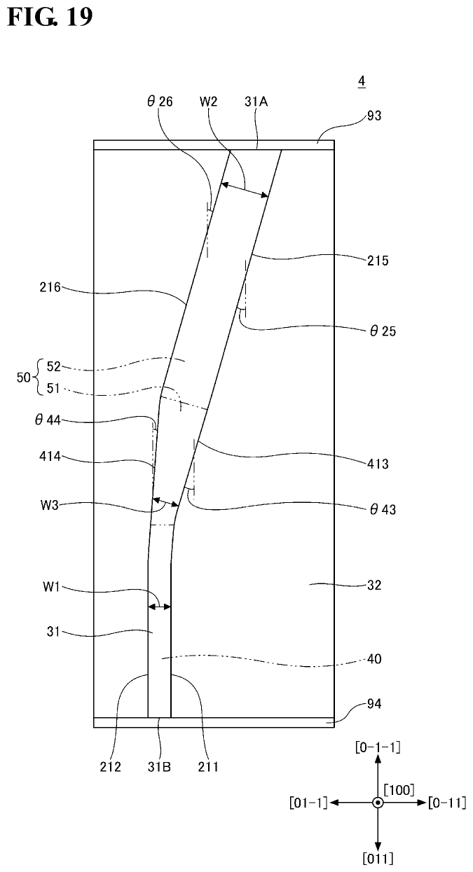

A fourth embodiment will be described. The fourth embodiment differs from the second embodiment primarily in the configuration of a tapered portion. FIG. 19 is a schematic diagram showing an optical semiconductor element according to the fourth embodiment. FIG. 19 shows the shape of a mesa in plan view.

As shown in FIG. 19, in an optical semiconductor element 4 according to the fourth embodiment, tapered portion 51 has a third surface 413 and a fourth surface 414 perpendicular to first main surface 20A. Third surface 413 is continuous with first surface 211 and fifth surface 215, and fourth surface 414 is continuous with second surface 212 and sixth surface 216. In a plane parallel to first main surface 20A, third surface 413 and fourth surface 414 are respectively inclined from a (0-11) plane and a (01-1) plane in directions identical to each other. The directions in which third surface 413 and fourth surface 414 are inclined are directions parallel to a (100) plane. The inclination of third surface 413 from the (0-11) plane is larger than the inclination of fourth surface 414 from the (01-1) plane. That is, in a plane parallel to first main surface 20A, third surface 413 is inclined more than fourth surface 414 from a {01-1} plane. Therefore, third distance W3 between third surface 413 and fourth surface 414 gradually increases as the distance from laser portion 40 increases. The magnitude of the angle formed by third surface 413 and the (0-11) plane is an angle θ43, the magnitude of the angle formed by fourth surface 414 and the (01-1) plane is an angle θ44, and angle θ43 is larger than angle θ44.

Third surface 413 and fifth surface 215 are flush with each other. That is, in a plane parallel to first main surface 20A, the size of the inclination of third surface 413 from the (0-11) plane is equal to the size of the inclination of fifth surface 215 from the (0-11) plane. Therefore, in a plane parallel to first main surface 20A, third surface 413 is inline from the (0-11) plane more by an angle of 0° than fifth surface 215. Angle θ43 is equal to angle θ25, and the difference between angle θ43 and angle θ25 is 0°.

In a plane parallel to first main surface 20A, fourth surface 414 is inclined from the (01-1) plane less by an angle larger than 0° and smaller than or equal to 3° than sixth surface 216, for example. For example, the difference between angle θ44 and angle θ26 is larger than 0° and smaller than or equal to 3°.

The other configurations of the fourth embodiment are similar to those of the second embodiment.

According to the fourth embodiment as well, reflection on first end surface 31A is suppressed and a high output is obtained. In addition, since semiconductor layer 80 is provided, light is confined in mesa 31, and emission of light to the outside of mesa 31 is suppressed.

Since third surface 413 and fifth surface 215 are flush with each other, the inclination of third surface 413 from the {01-1} plane is further suppressed, and the difference in the etching rate and the difference in the progress of the crystal growth are further suppressed.

In a plane parallel to first main surface 20A, fourth surface 414 is inclined from the (0-11) plane less by an angle larger than 0° and smaller than or equal to 3° than sixth surface 216, and it is easy to suppress the deviation of the optical axis between tapered portion 51 and parallel portion 52 to be small.

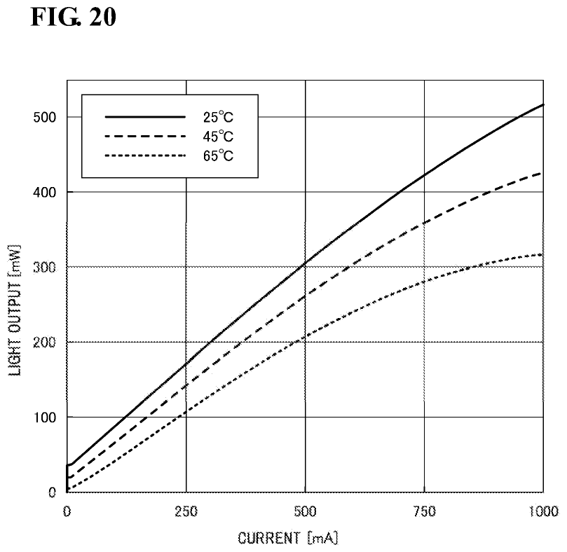

Here, results of experiments performed by the inventors of the present application on optical semiconductor element 1 according to the first embodiment will be described. In this experiment, a continuous wave (CW) was emitted by applying a current of 250 mA to laser portion 40, and the light output of optical semiconductor element 1 was measured while changing a current applied to optical amplifier portion 50. The temperature of a stage on which optical semiconductor element 1 was placed was 25° C., 45° C., or 65° C. The results are shown in FIG. 20. FIG. 20 is a diagram showing the relationship between the current applied to optical amplifier portion 50 and the light output of optical semiconductor element 1.

As shown in FIG. 20, when the temperature of the stage was 25° C., a light output of 350 mW was obtained when the current applying to optical amplifier portion 50 was 590 mA. Further, when the temperature of the stage was 45° C., the light output of 350 mW was obtained when the current applying to optical amplifier portion 50 was 722 mA.

Although embodiments have been described in detail above, the present disclosure is not limited to the specific embodiments, and various modifications and changes can be made within the scope described in the claims.

What is claimed is:

1. An optical semiconductor element comprising:
a substrate having a first main surface whose plane orientation is {100};
a first semiconductor layer provided on the first main surface and in which a mesa is formed; and
a second semiconductor layer,
wherein the mesa has a laser portion and an optical amplifier portion,
wherein the laser portion has
a first surface perpendicular to the first main surface, and
a second surface perpendicular to the first main surface and parallel to the first surface, wherein the optical amplifier portion has
a third surface perpendicular to the first main surface and continuous with the first surface,
a fourth surface perpendicular to the first main surface and continuous with the second surface,
a fifth surface perpendicular to the first main surface and continuous with the third surface,
a sixth surface perpendicular to the first main surface, continuous with the fourth surface, and parallel to the fifth surface, and
an end surface perpendicular to the first main surface, continuous with the fifth surface and the sixth surface, and from which light is emitted,
wherein a first distance between the first surface and the second surface is smaller than a second distance between the fifth surface and the sixth surface,
wherein the first surface and the second surface are parallel to a {01-1} plane of the substrate,
wherein the end surface is perpendicular to the {01-1} plane,
wherein, in a plane parallel to the first main surface, the third surface and the fourth surface are inclined from the {01-1} plane in directions identical to each other,
wherein, in a plane parallel to the first main surface, the third surface is inclined more than the fourth surface from the {01-1} plane,
wherein, in a plane parallel to the first main surface, the fifth surface and the sixth surface are inclined from the {01-1} plane in a direction identical to the directions in which the third surface and the fourth surface are inclined, and
wherein the second semiconductor layer is in contact with the first surface, the second surface, the third surface, the fourth surface, the fifth surface, and the sixth surface.

2. The optical semiconductor element according to claim 1,
wherein, in a plane parallel to the first main surface, the fifth surface and the sixth surface are inclined at 6° to 8° from the {01-1} plane in a direction identical to the directions in which the third surface and the fourth surface are inclined.

3. The optical semiconductor element according to claim 1,
wherein, in a plane parallel to the first main surface, the third surface is inclined from the {01-1} plane more by an angle of 0° to 1° than the fifth surface.

4. The optical semiconductor element according to claim 1,
wherein, in a plane parallel to the first main surface, the fourth surface is inclined from the {01-1} plane less by an angle larger than 0° and smaller than or equal to 3° than the sixth surface.

5. The optical semiconductor element according to claim 1,
wherein a size of an inclination of the fifth surface from the third surface is equal to a size of an inclination of the sixth surface from the fourth surface.

6. The optical semiconductor element according to claim 1,
wherein the third surface and the fifth surface are flush with each other.

7. The optical semiconductor element according to claim 1,
wherein the substrate is an indium phosphide substrate.
